(19) United States
(12) Patent Application Publication
(10) Pub. No.: US 2024/0266172 A1
(43) Pub. Date: Aug. 8, 2024

(54) SEMICONDUCTOR STRUCTURE COMPRISING AN ELECTRICALLY CONDUCTIVE BONDING INTERFACE, AND ASSOCIATED MANUFACTURING METHOD

(71) Applicants: Commissariat À L'énergie Atomique Et Aux Énergies Alternatives, Paris (FR); Soitec, Bernin (FR)

(72) Inventors: Frédéric Allibert, Bernin (FR); Didier Landru, Le Champ-près-Froges (FR); Oleg Kononchuk, Theys (FR); Eric Guiot, Goncelin (FR); Gweltaz Gaudin, Crolles (FR); Julie Widiez, Grenoble Cedex (FR); Franck Fournel, Grenoble Cedex (FR)

(21) Appl. No.: 18/004,594

(22) PCT Filed: Jun. 8, 2021
(86) PCT No.: PCT/FR2021/051023

§ 371 Date: Apr. 30, 2024

(30) Foreign Application Priority Data
Jul. 6, 2020 (FR) FR2007138

(51) Int. Cl. H01L 21/18; H01L 21/02; H01L 21/04; H01L 21/324; H01L 23/00

(52) U.S. Cl. CPC H01L 21/187; H01L 21/02016; H01L 21/0485; H01L 21/324; H01L 24/83; H01L 2224/83894; H01L 2224/83948; H01L 2924/10253; H01L 2924/10272

(57) ABSTRACT

The invention relates to a semiconductor structure (100) that comprises a useful layer (10) made of monocrystalline semiconductor material and extending along a main plane (x, y), a support substrate (30) made of semiconductor material, and an interface area (20) between the useful layer (10) and the support substrate (30), the support substrate extending parallel to the main plane (x, y), the structure (100) being characterised in that the interface area (20) comprises nodules (21) that:—are electrically conductive, in that they contain a metal material forming ohmic contact with the useful layer (10) and the support substrate (30);—have a thickness, along an axis (z) normal to the main plane (x, y) , of less than or equal to 30 nm;—are separate or adjoining, the separate nodules (21) being separated from each other by regions (22) of direct contact between the useful layer (10) and the support substrate (30). The invention also relates to a method for manufacturing the structure (100).

### FIELD OF THE INVENTION

The present invention relates to the field of semiconductor materials for microelectronic components. In particular, it relates to a structure comprising a monocrystalline semiconductor layer and a semiconductor carrier substrate, which are joined at an electrically conductive bonding interface. The invention also relates to a process for producing such a structure.

### TECHNOLOGICAL BACKGROUND OF THE INVENTION

It is common practice to form a semiconductor structure by transferring a semiconductor working layer, of low thickness and high crystal quality, to a semiconductor carrier substrate of lower crystal quality. One well-known thin-layer transfer solution is the Smart Cut™ process, based on implanting light ions and joining by direct bonding at a bonding interface. In addition to the economic advantages related to slimming the high quality material of the working layer, the semiconductor structure may also provide advantageous properties, for example related to the thermal or electrical conductivity or the mechanical compatibility of the carrier substrate.

In the field of power electronics for example, it may additionally be advantageous to establish an electrical conduction between the working layer and the carrier substrate, so as to form vertical components. For example, in the case of a structure comprising a working layer made of monocrystalline silicon carbide and a carrier substrate made of silicon carbide of lower quality (whether monocrystalline or polycrystalline), the bonding interface has to exhibit the lowest resistivity possible, preferably lower than 1 mohm.cm² or even lower than 0.1 mohm.cm².

Some solutions of the prior art propose performing direct semiconductor-to-semiconductor bonding, between the working layer and the carrier substrate, in order to establish a vertical electrical conduction. However, it can be difficult to obtain a good-quality interface via such bonding.

F. Mu et al. (ECS Transactions, 86 (5) 3-21, 2018) implement direct bonding after activating the surfaces to be assembled by bombardment with argon (SAB: “surface activation bonding”): such a treatment prior to bonding generates a very high density of side bonds, which promote the formation of covalent bonds at the joining interface, and hence a high bonding energy. However, this method has the drawback of generating an amorphous layer at the joined surfaces, which negatively affects vertical electrical conduction between the thin layer and the carrier substrate. To overcome this problem, heavy doping of said surfaces is proposed, in particular in document EP3168862.

Other solutions of the prior art propose forming a conductive bond on the basis of metal layers deposited on the surfaces to be joined.

For example, the publication by Letertre (“Silicon carbide and related materials”, Material Science Forum—vol 389-393, April 2002) or document U.S. Pat. No. 7,208,392, describe the deposition of a layer of tungsten and of a layer of silicon in order to form a conductive intermediate layer based on tungsten silicide (WSi2). One drawback of this approach may arise from the formation of voids in this intermediate layer, due to the contraction of the silicide with respect to the initially deposited materials: in particular, this may affect the quality of the surface semiconductor layer and of the semiconductor structure as a whole, to the point of making it unusable for the target applications. In addition, it is difficult to lower the resistivity of the bonding interface to the level required by some applications which require very good vertical electrical conduction.

### SUBJECT OF THE INVENTION

The present invention relates to an alternative solution to those of the prior art, and aims to completely or partly overcome the abovementioned drawbacks. In particular, it relates to a structure comprising a monocrystalline semiconductor working layer and a semiconductor carrier substrate, which are joined at an electrically conductive bonding interface. The invention also relates to a process for producing such a structure.

### BRIEF DESCRIPTION OF THE INVENTION

The invention relates to a semiconductor structure comprising a working layer made of monocrystalline semiconductor material, extending in a main plane, a carrier substrate made of semiconductor material, and an interface zone between the working layer and the carrier substrate, extending parallel to the main plane. The structure is noteworthy in that the interface zone comprises nodules:
that are electrically conductive, comprising a metal material forming an ohmic contact with the working layer and with carrier substrate,
that have a thickness, along an axis normal to the main plane, that is less than or equal to 30 nm,
that are disjunct or joined, the disjunct nodules being separated from one another by regions of direct contact between the working layer and the carrier substrate.

According to other advantageous and non-limiting features of the invention, taken alone or in any technically feasible combination:
the working layer and the carrier substrate are formed of the same semiconductor material and have an identical doping type;
the semiconductor material of the working layer is chosen from among silicon carbide, silicon, gallium nitride and germanium;
the semiconductor material of the carrier substrate is chosen from among silicon carbide, silicon, gallium nitride and germanium, and has a monocrystalline, polycrystalline or amorphous structure;
the metal material of the nodules is chosen from among tungsten, titanium, nickel, aluminium, molybdenum, niobium, tantalum, cobalt and copper;
the degree of coverage of the nodules in the median plane of the interface zone is between 1% and 70%;
the nodules have a resistivity lower than 0.1 mohm.cm², preferably lower than or equal to 0.01 mohm.cm², so as to obtain a resistivity of the interface zone lower than 0.1 mohm.cm², preferably lower than or equal to 0.01 mohm.cm²;
the nodules have a thickness of less than or equal to 20 nm, or even less than or equal to 10 nm.

The invention also relates to a power component produced on and/or in the working layer of a semiconductor structure as above, and comprising at least one electrical contact on and/or in the carrier substrate, at the level of a back face of the semiconductor substrate.

Lastly, the invention relates to a process for producing a structure as above, comprising the following steps:

a) providing a working layer made of monocrystalline semiconductor material having a free face to be joined,

b) providing a carrier substrate made of semiconductor material having a free face to be joined,

c) depositing a film made of a metal material able to form an ohmic contact with the working layer and with the carrier substrate and having a thickness of less than or equal to 20 nm on the free face to be joined of the working layer and/or on the free face to be joined of the carrier substrate under a non-oxidizing controlled atmosphere,

d) forming an intermediate structure comprising an operation of directly joining the free faces to be joined of the working layer and of the carrier substrate, respectively, under a non-oxidizing controlled atmosphere, the intermediate structure including an encapsulated film originating from the one or more films deposited in step c),

e) annealing the intermediate structure at a temperature higher than or equal to a critical temperature, so as to cause the segmentation of the encapsulated film into electrically conductive nodules forming an ohmic contact with the working layer and with the carrier substrate, and form the interface zone.

According to other advantageous and non-limiting features of the invention, taken alone or in any technically feasible combination:
the working layer and the carrier substrate are formed of the same semiconductor material and have an identical doping type;
step a) comprises an operation of implanting light species into a donor substrate so as to form a buried weakened plane that delimits, with a front face of the donor substrate, the working layer;
step a) comprises the formation of the donor substrate by epitaxially growing a donor layer on an initial substrate, the implantation being performed later, into the donor layer;
step d) comprises, after the direct joining giving rise to a bonded assembly comprising the donor substrate and the carrier substrate, a separation at the level of the buried weakened plane so as to form, on the one hand, the intermediate structure comprising the working layer, the encapsulated film and the carrier substrate and, on the other hand, the remainder of the donor substrate;
the production process comprises, prior to deposition step c), a step c′) of deoxidation of the free face to be joined of the working layer and/or of the free face to be joined of the carrier substrate;
the deposition of step c) and the direct joining of step d) are performed in one and the same apparatus;
the thickness of the film deposited in step c) is less than or equal to 10 nm, or even less than or equal to 5 nm, or even less than or equal to 2 nm;
steps c) and d) are performed in vacuum;
deposition step c) is performed at ambient temperature, using a sputtering technique;
the semiconductor material of the working layer is chosen from among silicon carbide, silicon, gallium nitride and germanium;
the semiconductor material of the carrier substrate is chosen from among silicon carbide, silicon, gallium nitride and germanium, and has a monocrystalline, polycrystalline or amorphous structure;
the metal material of the film is chosen from among tungsten, titanium, nickel, aluminium, molybdenum, niobium, tantalum, cobalt and copper;
the critical temperature is between 500° C. and 1800° C., depending on the nature of the metal material of the encapsulated film and of the one or more semiconductor materials of the working layer and of the carrier substrate.

### BRIEF DESCRIPTION OF THE FIGURES

Other features and advantages of the invention will become apparent from the following detailed description of the invention, which is given with reference to the appended figures, in which:

FIG. 1 presents a structure in accordance with the invention;

FIG. 2a

FIG. 2b

FIG. 2c

FIG. 2d

FIGS. 2a to 2e present steps of a production process in accordance with the invention;

FIG. 3a

FIG. 3b

FIG. 3c

FIGS. 3a to 3d present variants of steps of a production process in accordance with the invention;

FIG. 4 shows a curve of current as a function of applied voltage, measured using two electrodes formed on a structure in accordance with the invention, the path of the current passing through the interface zone of said structure; FIG. 4 also shows a current/voltage curve for a bulk substrate and for a bonded structure not in accordance with the invention, by way of comparison.

FIG. 5 shows a graph relating the resistivity of the nodules in the interface zone of a structure in accordance with the invention and the degree of coverage of said nodules, in order to obtain various levels of resistivity of the interface zone.

FIG. 6 shows a graph of current as a function of voltage, illustrating the change in the resistivity of the interface zone according to the thickness of the film made of metal material deposited before the formation of the intermediate structure.

### DETAILED DESCRIPTION OF THE INVENTION

In the description, the same reference numerals in the figures may be used for elements of the same type. The figures are schematic representations which, for the sake of readability, are not to scale. In particular, the thicknesses of the layers along the z-axis are not to scale with respect to the lateral dimensions along the x- and y-axes; and the relative thicknesses of the layers with respect to one another are not respected in the figures.

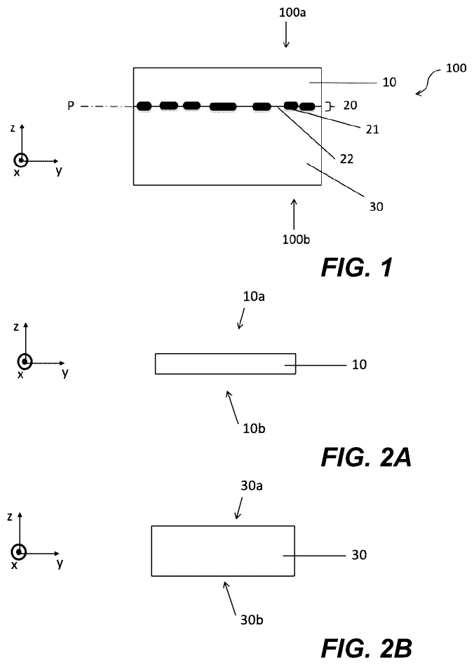

The invention relates to a semiconductor structure 100 comprising a working layer 10 made of monocrystalline semiconductor material, a carrier substrate 30 made of semiconductor material, and an interface zone 20 between the working layer 10 and the carrier substrate 30 (FIG. 1). Like the working layer 10, the interface zone 20 extends parallel to the main plane (x,y).

Advantageously, and as is typically the case in the field of microelectronics, the semiconductor structure 100 takes the form of a circular wafer, the diameter of which is between 100 mm and 450 mm and the total thickness of which is typically between 300 microns and 1000 microns. It is understood that, in this case, the carrier substrate 30 and the working layer 10 also take such a circular shape. The (circular) front 100a and back 100b faces of the wafer extend parallel to the main plane (x,y).

Numerous types of semiconductor structure 100 allowing vertical electrical conduction between the working layer 10 and the carrier substrate 30 may be of interest for microelectronics applications: the nature of the materials making up the working layer 10 and the carrier substrate 30 may therefore vary greatly. For example, the semiconductor material of the working layer 10 may be chosen from among silicon carbide, silicon, gallium nitride and germanium. In general, the production of components on the working layer 10 requires said layer 10 to exhibit a high crystal quality: it is therefore chosen so as to be monocrystalline, with a quality grade, a type and a level of doping matched to the target application.

Still by way of example, the semiconductor material of the carrier substrate 30 may be chosen from among silicon carbide, silicon, gallium nitride and germanium. It preferably exhibits a lower quality level, essentially for economic reasons, and a monocrystalline, polycrystalline or amorphous structure. Its type and its level of doping are chosen so as to suit the target application.

The interface zone 20 of the semiconductor structure 100 according to the invention is noteworthy in that it comprises electrically conductive nodules 21. Each of these nodules 21 comprises a metal material able to form an ohmic contact with the working layer 10 and with the carrier substrate 30. Without being limiting, the metal material of the nodules 21 may be chosen from among tungsten, titanium, nickel, aluminium, molybdenum, niobium, tantalum, cobalt and copper. As is known to those skilled in the art, not all of these materials are capable of forming an ohmic contact with all of the semiconductor materials mentioned as being able to form the working layer 10 and/or the carrier substrate 30. The metal material of the nodules 21 will therefore be chosen according to the nature of the working layer 10 and of the carrier substrate 30. A few particular examples will be described further below.

The nodules 21 of the interface zone 20 further exhibit a thickness, along an axis z normal to the main plane (x,y) that is low or even very low: typically less than or equal to 30 nm, less than or equal to 20 nm, less than or equal to 10 nm, or even less than or equal to 5 nm.

The nodules 21, distributed in the interface zone 20, are disjunct or joined; disjunct nodules are mainly separated from one another by regions 22 in which the working layer 10 makes direct contact with the carrier substrate 30, in other words in which there is a direct bond between the semiconductor materials of the working layer 10 and of the carrier substrate 30. These regions 22 will be referred to hereinafter as regions of direct contact 22.

Potentially, in some cases of semiconductor structure 100, there may be cavities of nanometre thickness in these contact regions 22, but said cavities occupy less than 20%, or less than 10%, or even less than 5% of the area in the main plane (x,y) occupied by the contact regions 22. Their thickness is also less than that of the nodules 21.

The semiconductor structure 100 according to the invention guarantees excellent electrical conductivity between the working layer 10 and the carrier substrate 30, via its interface zone 20. In particular, the nodules 21, distributed in the interface zone 20 in a median plane P that is substantially parallel to the main plane (x,y), establish ohmic contact with the working layer 10 and with the carrier substrate 30, and are at least partly formed by a metal material that is a very good electrical conductor. They thus allow effective vertical electrical conduction.

Between disjunct nodules 21, the regions of direct contact 22 may potentially allow electrical conduction but this is less effective than with the nodules 21. However, these regions of direct contact 22 ensure the mechanical continuity of the interface zone 20 and provide excellent mechanical strength between the working layer 10 and the carrier substrate 30. The quality of the working layer 10 is therefore not affected by potential voids or interface defects; it is noted that the aforementioned cavities, when present, have dimensions and a density that do not negatively affect the quality and mechanical strength of the working layer 10.

In a median plane P of the interface zone 20, the degree of coverage of the nodules 10 is typically between 1% and 70%, preferably between 10% and 60%.

Preferably, the nodules 21 exhibit a resistivity lower than 0.1 mohm.cm², or even lower than or equal to 0.01 mohm.cm². A resistivity in ohm.cm² is used here for the nodules 21 (or for the interface zone 20 more generally) because of their very low thickness.

The resistivity of the nodules 21 includes the resistivity of the metal material forming the nodules 21, the specific contact resistance between the nodules 21 and the working layer 10, and the specific contact resistance between the nodules 21 and the carrier substrate 30. It is these contact resistances which dominate the overall vertical resistance. As such, it makes sense to refer to surface resistivity in ohm.cm². The specific contact resistances may differ, depending on the nature and/or the doping of the respective materials of the working layer 10 and of the carrier substrate 30. By way of example, the specific contact resistance of a nodule made of nickel (Ni) with silicon carbide (SiC) featuring an N-type doping (nitrogen or phosphorus dopant) level of 4E15/cm³ will be of the order of 3 mΩ.cm², while that for an N-type doping level of 1E19/cm³ will be about 0.003 mΩ.cm².

The graph of FIG. 5 shows the change in the resistivity of the interface zone 20 as a function of the resistivity of the nodules 21 and of their degree of coverage in the median plane P. As mentioned above, the target resistivity of the interface zone 20, for power applications, is lower than or equal to 1 mohm.cm², or even lower than or equal to 0.1 mohm.cm².

According to one advantageous embodiment, the working layer 10 and the carrier substrate 30 are formed of the same semiconductor material and feature an identical doping type, in order to allow effective vertical electrical conduction between the components that will be produced in and/or on the working layer 10 and the components and/or the electrode that will be produced on the back face 30b of the carrier substrate 30 of the structure 100.

According to a first example, a semiconductor structure 100 according to the present invention comprises a working layer 10 made of high-quality monocrystalline silicon carbide; what is meant by high quality is typically a SiC with fewer than one micropipe (MP) per cm², fewer than 500 threading screw dislocations (TSDs) per cm², fewer than 5000 threading edge dislocations (TEDs) per cm², fewer than 1000 basal plane dislocations (BPDs) per cm² and fewer than 1 stacking fault (SF)/cm. The SiC of the working layer 10 features N-type doping at 8×10¹⁸/cm³. The semiconductor structure 100 also comprises a carrier substrate 30 made of low-quality monocrystalline or polycrystalline silicon carbide, featuring N-type doping with a resistivity of the order of 20 ΩQ.cm. The nodules 21 are made of tungsten (W); they may have a thickness of the order of 5 nm, and a degree of coverage of between 15% and 25%. The resistivity of the interface zone 20 of such a structure 100 is of the order of 0.05 mohm.cm², i.e. lower than or equal to 0.1 mohm.cm².

According to a second example, a semiconductor structure 100 according to the present invention comprises a working layer 10 made of high-quality monocrystalline silicon carbide, featuring P-type doping at 1×10¹⁹/cm³, and a carrier substrate 30 made of low-quality monocrystalline or polycrystalline silicon carbide, featuring P-type doping at 5×10¹⁹/cm³. The nodules 21 of the interface zone 20 are made of titanium (Ti); they have a thickness of the order of 6 nm, and a degree of coverage of between 30% and 40%. The resistivity of the interface zone 20 of such a structure 100 is lower than 1 mohm.cm².

According to a third example, a semiconductor structure 100 according to the invention comprises a working layer 10 made of high-quality monocrystalline silicon, featuring N-type doping at 5×10¹⁹/cm³, and a carrier substrate 30 made of low-quality monocrystalline or polycrystalline silicon carbide, featuring N-type doping at 5×10¹⁹/cm³. The nodules 21 are made of aluminium (Al); they have a thickness of the order of 3 nm, and a degree of coverage of between 5% and 15%. The resistivity of the interface zone 20 of such a structure 100 is lower than 1 mohm.cm².

Of course, this list of examples is not exhaustive and many other semiconductor structures 100 in accordance with the invention may be produced, based on various combinations of materials for the working layer 10, the nodules 21 and the carrier substrate 30, while observing the conditions mentioned above for the interface zone 20.

In particular, power components may be produced on and/or in the working layer 10 of a semiconductor structure 100 according to the invention. These components may in particular comprise at least one electrical contact on and/or in the carrier substrate 30, at the level of a back face 100b of the semiconductor structure 100. By way of non-limiting examples, these power components may comprise transistors, diodes, thyristors or passive components (capacitors, inductors, etc.), etc.

The invention also relates to a process for producing a semiconductor structure 100 as described above.

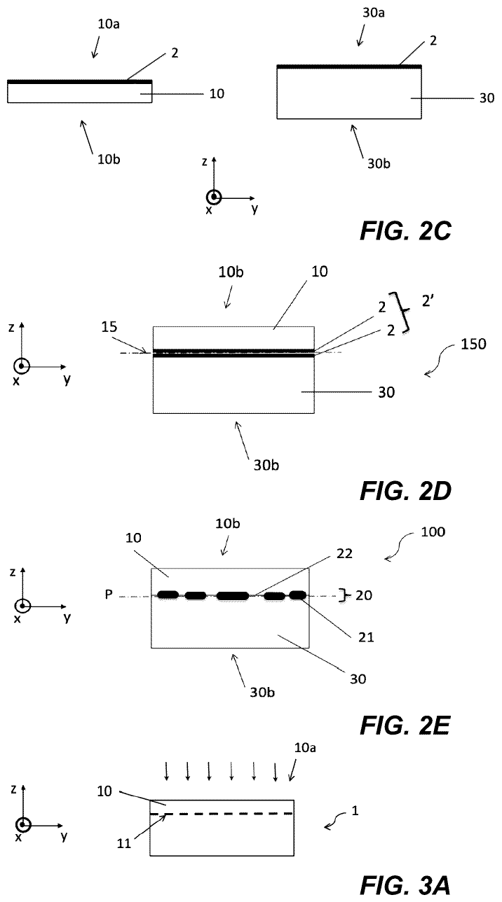

The production process first comprises a step a) of providing the working layer 10 made of monocrystalline semiconductor material (FIG. 2a). In this step a), the working layer 10 has a free face 10a that is intended to be joined in a later step of the process, which is also referred to as the front face 10a; it also has a back face 10b opposite its front face 10a.

According to one advantageous implementation, the working layer 10 results from the transfer of a surface layer from a donor substrate 1, in particular a layer transfer based on the Smart Cut process.

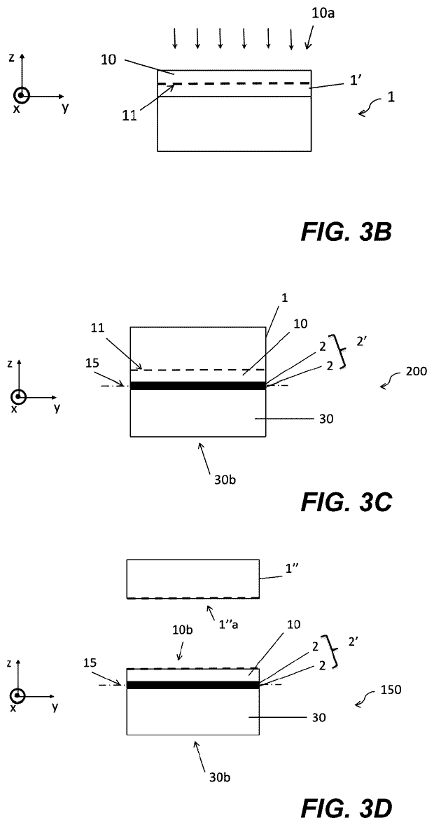

Step a) may thus comprise an operation of implanting light species, for example hydrogen, helium or a combination of these two species, into a donor substrate 1 in order to form a buried weakened plane 11 that delimits, with a front face 10a of the donor substrate 1, the working layer 10 (FIG. 3a).

According to one variant of this implementation, step a) comprises the formation of the donor substrate 1 by epitaxially growing a donor layer 1′ on an initial substrate, prior to the implantation of the light species (FIG. 3b). This variant makes it possible to form a donor layer 1′ that exhibits the structural and electrical characteristics required for the target application. In particular, excellent crystal quality may be obtained by epitaxy, and in-situ doping of the donor layer 1′ may be precisely controlled. The light species are then implanted into the donor layer 1′ to form the buried weakened plane 11.

Alternatively, the working layer 10 provided in step a) may of course be formed using other known techniques for transferring thin layers.

The production process according to the invention next comprises a step b) of providing a carrier substrate 30 made of semiconductor material (FIG. 2b). The carrier substrate 30 has a free face 30a that is intended to be joined in a later step of the process, which is also referred to as the front face 30a; it also has a back face 30b.

As mentioned above in the description of the semiconductor structure 100, the working layer 10 may be formed of one or more materials chosen from among silicon carbide, silicon, gallium nitride and germanium; and the carrier substrate 30 may be formed of one or more materials chosen from among silicon carbide, silicon, gallium nitride and germanium, preferably of lower quality, whether monocrystalline, polycrystalline or even amorphous.

According to one particular embodiment, the working layer 10 and the carrier substrate 30 are formed of the same semiconductor material and feature an identical doping type (N or P).

The production process next comprises a step c) of depositing a film 2 made of metal material on the free face to be joined 10a of the working layer 10 or on the free face to be joined 30a of the carrier substrate 30 or else, as illustrated in FIG. 2c, on both free faces to be joined 10a, 30a. The metal material is chosen for its suitability for forming an ohmic contact with the working layer 10 and with the carrier substrate 30. It may be chosen from the following non-limiting list of materials: tungsten, titanium, nickel, aluminium, molybdenum, niobium, tantalum, cobalt, copper, depending on the nature of the working layer 10 and of the carrier substrate 30.

The thickness of the film 2 is less than or equal to 20 nm, preferably less than or equal to 10 nm, or even less than or equal to 5 nm. For example, the deposited film 2 may have a thickness of the order of 0.5 nm, 1 nm, 2 nm, 3 nm, 4 nm, 5 nm, 8 nm, 10 nm or 15 nm.

It is noted that when a film 2 is deposited on both free faces 10a, 30a, the total deposited thickness, i.e., the sum of the thicknesses of film 2 deposited on each of the free faces 10a, 30a, is preferably less than or equal to 20 nm, or even less than or equal to 10 nm. The total thickness of deposited film 2 has to be kept low, in order to allow segmentation of the film into nodules 21 in a later step of the process.

The film 2 is deposited under a non-oxidizing controlled atmosphere. It is important for the metal film 2 not to undergo any oxidation or to be marred by contaminants from the surrounding atmosphere. Typically, the deposition in step c) is performed in high vacuum, of the order of 10⁻⁶ Pa or less.

Depending on the nature of the deposited film 2, step c) is performed at ambient temperature or at low temperature, advantageously by means of a sputtering deposition technique using, to bombard the metal target, a neutral element or one whose residual presence in the deposited metal is not disruptive (Ar, Si, N, etc.).

According to one particular implementation, the production process according to the invention comprises, prior to deposition step c), a step c′) of deoxidation of the free face to be joined 10a of the working layer 10 and/or of the free face to be joined 30a of the carrier substrate 30. Such a step allows the removal of any native oxide present on the surface of the working layer 10 and/or of the carrier substrate 30, which facilitates the formation of an ohmic contact with the metal material in a later step of the process. The deoxidation may be performed by wet (removal by attacking with HF for example) or dry (dry etching or annealing under a reducing atmosphere) chemical treatment.

The production process next comprises a step d) of forming an intermediate structure 150, which step comprises an operation of directly joining the free faces to be joined 10a, 30a of the working layer 10 and of the carrier substrate 30, respectively, at a bonding interface 15 (FIG. 2d).

This direct joining is preferably performed by means of bonding by molecular adhesion, which consists in placing the faces to be joined 10a, 30a in contact under a non-oxidizing controlled atmosphere. This may be direct bonding between the working layer 10 and the film 2 when this film has only been deposited on the carrier substrate 30, or direct bonding between the carrier substrate 30 and the film 2 when this film has only been deposited on the working layer 10, or else direct bonding between two films 2 when they have been deposited on the working layer 10 and on the carrier substrate 30.

The direct joining is preferably performed under a controlled atmosphere and in particular in high vacuum, of the order of 10⁻⁶ Pa or less.

Advantageously, the deposition of step c) and the direct joining in step d) are performed one after the other without interrupting the vacuum, in situ or in a multi-chamber apparatus. By way of example, the BV7000 atomic diffusion bonding apparatus by Canon is cited, in which it is possible to successively perform metal deposition and direct bonding while maintaining a controlled atmosphere.

With reference to the advantageous implementation illustrated in FIGS. 3a to 3d, step d) comprising the direct joining of the free face to be joined 10a of the working layer 10 to the free face to be joined 30a of the carrier substrate 30 gives rise to a bonded assembly 200 including the donor substrate 1, the carrier substrate 30, and the bonding interface 15 (FIG. 3c). Step d) further comprises separation at the level of the buried weakened plane 11 so as to form, on the one hand, the intermediate structure 150 comprising the working layer 10, the one or more films 2 and the carrier substrate 30 and, on the other hand, the remainder of the donor substrate 1″ (FIG. 3d). Such a separation may be performed during a heat treatment capable of making cavities and microcracks, caused by the implanted species, grow in the buried weakened layer 11. The separation may also be performed by applying a mechanical stress, or else through the combination of thermal and mechanical stresses, as is well known with reference to the Smart Cut process.

Sequences of cleaning, smoothing, polishing or etching the separated face 10b of the working layer 10 and/or the separated face 1″a of the remainder of the donor substrate 1″ may be carried out in order to restore good surface quality, in particular in terms of roughness, defect density and other contamination.

Whatever the implementation of the process, on completion of step d), the intermediate structure 150 has a front face 10b on the side of the working layer 10, a back face 30b on the side of the carrier substrate 30, and an encapsulated film 2′ between the working layer 10 and the carrier substrate 30. It is noted that the encapsulated film 2′ corresponds to the film 2 when this film has been deposited only on one of the free faces to be joined 10a, 30a, or corresponds to both films 2 deposited on the working layer 10 and on the carrier substrate 30, respectively.

The production process according to the invention next comprises a step e) of annealing the intermediate structure 150 at a temperature higher than or equal to a critical temperature, so as to cause the segmentation of the encapsulated film 2′ into electrically conductive nodules 21 and form the interface zone 20 (FIG. 2e). Step e) results in the formation of the semiconductor structure 100.

The critical temperature refers here to the temperature from which the contact between the metal of the encapsulated film 2′ and the semiconductor of the working layer 10 and of the carrier substrate 30 becomes ohmic: for example, between 400° C. and 650° C. for the Al/Si pair, between 950° C. and 1100° C. for the Ni/SiC pair, etc. Additionally, the critical temperature has to be high enough to allow the bonding of the regions of direct contact 22, between nodules 21.

It is typically between 500° C. and 1800° C., depending on the nature of the metal material and of the one or more semiconductor materials of the semiconductor structure 100.

Beyond this critical temperature, the system including the encapsulated film 2′ and the semiconductor surfaces of the working layer 10 and of the carrier substrate 30 in contact with the said film 2′ will optimize its surface energy by clustering the encapsulated film 2′ into nodules 21 establishing ohmic contact with the semiconductor surfaces, and by creating regions of direct contact 22 between the semiconductor surfaces of the working layer 10 and of the carrier substrate 30, respectively.

Furthermore, because the encapsulated film 2′ is extremely thin, metal materials that are known to be stable at low or medium temperature only may be used in semiconductor structures 100 in accordance with the invention that are able to undergo treatments at high (900° C.-1100° C.) or even very high (1200° C.-1800° C.) temperatures: specifically, because of their clustering into nodules 21 of small size and very low thickness, they do not cause deterioration of the structure 100 and in particular of the working layer 10. For example, reference may be made to the case of nodules 21 made of nickel or of titanium in a structure 100 comprising a working layer 10 and a carrier substrate 30 made of SiC and intended to undergo epitaxy at a temperature of between 1600° C. and 1800° C.

The production process as described therefore makes it possible to obtain a semiconductor structure 100 that provides vertical electrical conduction between the working layer 10 and the carrier substrate 30 via an interface zone 20. The very thin nodules 21 are largely made of metal and therefore exhibit very low resistivity. Furthermore, the presence of regions of direct contact 22 between disjunct nodules 21 avoids any problem with the mechanical strength or more generally reliability of the working layer 10 and/or of the components that will be produced on or in this layer. Lastly, because the invention is based on joining via a metal film 2, the increase in interface resistivity related to the direct bonding of semiconductor materials of different crystallographic nature is not an issue for vertical electrical conduction in structure 100 since the nodules 21 ensure said conduction.

### Exemplary Implementation

The donor substrate 1 is made of high-quality monocrystalline 4H SiC and has a diameter of 150 mm. The donor substrate 1 is N-doped, with a resistivity of the order of 20 mohm.cm. It is implanted through its front face 1a, which is a “C” face, with hydrogen ions at a dose of 5^{E}16/cm² and an energy of 95 keV. Around the implantation depth, a buried weakened plane 11 is thus defined, delimiting, with the front face 10a of the donor substrate 1, the working layer 10.

The carrier substrate 30 is made of monocrystalline 4H SiC of lower quality, with the same diameter as the donor substrate 1. It is N-doped, with a resistivity of the order of 20 mohm.cm. The two substrates 1, 30 undergo cleaning sequences, in order to remove particles and other surface contaminants. The sequences are preferably chosen so that the surfaces of the substrates 1, 30 do not undergo oxidation (absence of native oxide).

The substrates 1, 30 are introduced into a first deposition chamber, integrated into a direct bonding apparatus. A tungsten film 2 with a thickness of 0.5 nm is deposited on each of the front faces 10a, 30a (free faces to be joined) of the substrates 1, 30, in vacuum, at 10⁻⁶ Pa and at ambient temperature, by sputtering.

The substrates 1, 30 are introduced into a second bonding chamber, so as to be joined at their front faces 10a, 30a, by placing the films 2 deposited on the donor substrate 1 and on the carrier substrate 30, respectively, in direct contact. The atmosphere in the bonding chamber is the same as that in the deposition chamber, which prevents any oxidation or passivation of the surface of the films 2.

After joining, the bonded assembly 200 comprises the donor substrate 1 connected to the carrier substrate 30 via a bonding interface 15, and the encapsulated film 2′ formed of the two films 2 deposited and buried between the two substrates 1, 30. The encapsulated film 2′ has a thickness of the order of 1 nm. The bonded assembly 200 is subjected to a heat treatment in order to cause separation at the buried weakened plane 11, at a temperature of around 900° C. for 30 minutes. What is obtained is then the intermediate structure 150 including a working layer 10 having a thickness of 500 nm, arranged on the encapsulated film 2′, which is itself arranged on the carrier substrate 30. Cleaning and polishing sequences are applied so as to restore the satisfactory level of defect density and roughness to the surface 10b of the working layer 10.

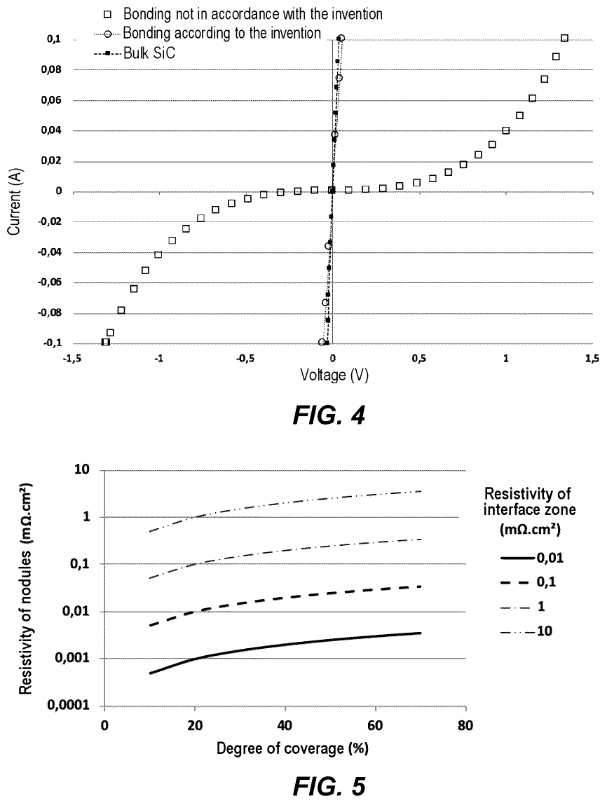

Lastly, an anneal at 1700° C. for 30 minutes is applied to the intermediate structure 150, which was previously provided with a protective layer on its front face 10b (also free face 10b of the working layer 10 in the intermediate structure 150). On completion of this anneal, what is obtained is the structure 100 according to the invention: the interface zone 20 is formed and the nodules 21 made of tungsten, separated by regions of direct contact 20 between working layer 10 and carrier substrate 30, provide the structure 100 with excellent vertical electrical conductivity, nearly identical to that of a bulk SiC substrate exhibiting a resistivity of 20 mohm.cm. This is apparent in the graph of FIG. 4 which illustrates curves of current as a function of voltage I(V) for simple components comprising two metal contact electrodes. In the case of the structure 100 according to the invention, the I(V) measurement is taken at two electrodes between which the path of the current passes through the interface zone 20. The interface zone 20 has a resistivity lower than or equal to 0.1 mohm.cm².

The nodules 21 in this structure 100 have a thickness of the order of 5 nm and a mean diameter of the order of 20 nm. The degree of coverage of the nodules 21 in a median plane of the interface zone 20 is of the order of 20%.

The graph of FIG. 4 shows, by way of comparison, as “bonding not in accordance with the invention”, the I(V) curve of a structure based on direct SiC/SiC bonding with heavy doping (nitrogen implantation) of the joined surfaces, the SiC substrates having the same resistivity as in the aforementioned structure 100. The improvement in terms of resistivity of the interface zone provided by the present invention is clearly apparent in FIG. 4.

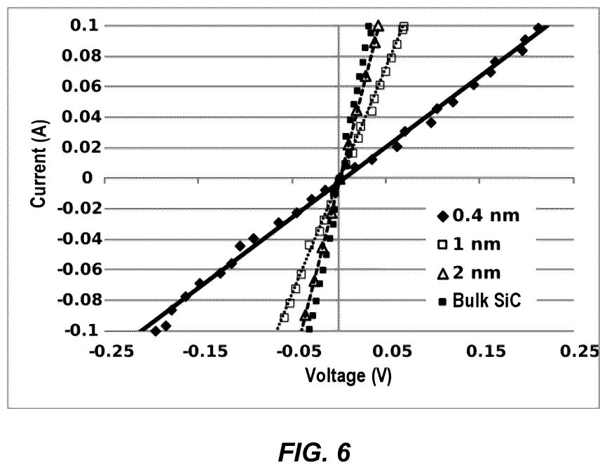

Under the same experimental conditions as those described above, it has been observed that the resistivity of the interface zone 20 could be decreased further with a thickness of encapsulated film 2′ of the order of 2 nm, or even 3 nm. FIG. 6 shows the effect on the I(V) curve of thicknesses of the encapsulated film 2′ ranging from 0.4 nm to 2 nm: the I(V) curve for an encapsulated film 2′ with a thickness of 2 nm is very close to that obtained with a bulk SiC substrate.

Of course, the invention is not limited to the described embodiments and examples, and alternative embodiments may be introduced thereto without departing from the scope of the invention as defined by the claims.

1. Semiconductor structure (100) comprising a working layer (10) made of monocrystalline semiconductor material, extending in a main plane (x,y), a carrier substrate (30) made of semiconductor material, and an interface zone (20) between the working layer (10) and the carrier substrate (30), extending parallel to the main plane (x,y), the structure (100) being characterized in that the interface zone (20) comprises nodules (21):
that are electrically conductive, comprising a metal material forming an ohmic contact with the working layer (10) and with carrier substrate (30),
that have a thickness, along an axis (z) normal to the main plane (x,y), that is less than or equal to 30 nm,
that are disjunct or joined, the disjunct nodules (21) being separated from one another by regions of direct contact (22) between the working layer (10) and the carrier substrate (30).

2. Semiconductor structure (100) according to the preceding claim, wherein the working layer (10) and the carrier substrate (30) are formed of the same semiconductor material and have an identical doping type.

3. Semiconductor structure (100) according to either of the preceding claims, wherein the semiconductor material of the working layer (10) is chosen from among silicon carbide, silicon, gallium nitride and germanium.

4. Semiconductor structure (100) according to one of the preceding claims, wherein the semiconductor material of the carrier substrate (30) is chosen from among silicon carbide, silicon, gallium nitride and germanium, and has a monocrystalline, polycrystalline or amorphous structure.

5. Semiconductor structure (100) according to one of the preceding claims, wherein the metal material of the nodules (21) is chosen from among tungsten, titanium, nickel, aluminium, molybdenum, niobium, tantalum, cobalt and copper.

6. Semiconductor structure (100) according to one of the preceding claims, wherein the degree of coverage of the nodules (21) in a median plane (P) of the interface zone (20) is between 1% and 70%.

7. Semiconductor structure (100) according to one of the preceding claims, wherein the nodules (21) have a resistivity lower than 0.1 mohm.cm², preferably lower than or equal to 0.01 mohm.cm², so as to obtain a resistivity of the interface zone (20) lower than 0.1 mohm.cm², preferably lower than or equal to 0.01 mohm.cm².

8. Semiconductor structure (100) according to one of the preceding claims, wherein the nodules (21) have a thickness of less than or equal to 20 nm, or even less than or equal to 10 nm.

9. Power component produced on and/or in the working layer (10) of a semiconductor structure (100) according to one of the preceding claims, and comprising at least one electrical contact on and/or in the carrier substrate (30), at the level of a back face of the semiconductor substrate (100).

10. Process for producing a semiconductor structure (100) according to one of claims 1 to 8, comprising the following steps:
a) providing a working layer (10) made of monocrystalline semiconductor material having a free face (10a) to be joined,
b) providing a carrier substrate (30) made of semiconductor material having a free face (30a) to be joined,
c) depositing a film (2) made of a metal material able to form an ohmic contact with the working layer (10) and with the carrier substrate (30) and having a thickness of less than or equal to 20 nm on the free face (10a) to be joined of the working layer (10) and/or on the free face (30a) to be joined of the carrier substrate (30) under a non-oxidizing controlled atmosphere,
d) forming an intermediate structure (150) comprising an operation of directly joining the free faces to be joined of the working layer (10) and of the carrier substrate (30), respectively, under a non-oxidizing controlled atmosphere, the intermediate structure (150) including an encapsulated film (2′) originating from the one or more films (2) deposited in step c),
e) annealing the intermediate structure (150) at a temperature higher than or equal to a critical temperature, so as to cause the segmentation of the encapsulated film (2′) into electrically conductive nodules (21) forming an ohmic contact with the working layer (10) and with the carrier substrate (30), and form the interface zone (20).

11. Production process according to the preceding claim, wherein the working layer (10) and the carrier substrate (30) are formed of the same semiconductor material and have an identical doping type.

12. Production process according to either of the two preceding claims, wherein step a) comprises an operation of implanting light species into a donor substrate (1) so as to form a buried weakened plane (11) that delimits, with a front face (10a) of the donor substrate (1), the working layer (10).

13. Production process according to the preceding claim, wherein step a) comprises the formation of the donor substrate (1) by epitaxially growing a donor layer (1′) on an initial substrate, the implantation being performed later, into the donor layer (1′).

14. Production process according to either of the two preceding claims, wherein step d) comprises, after the direct joining giving rise to a bonded assembly (200) comprising the donor substrate (1) and the carrier substrate (30), a separation at the level of the buried weakened plane (11) so as to form, on the one hand, the intermediate structure (150) comprising the working layer (10), the encapsulated film (2′) and the carrier substrate (30) and, on the other hand, the remainder of the donor substrate (1″).

15. Production process according to one of the five preceding claims, comprising, prior to deposition step c), a step c′) of deoxidation of the free face (10a) to be joined of the working layer (10) and/or of the free face (30a) to be joined of the carrier substrate (30).

16. Production process according to one of the six preceding claims, wherein the deposition of step c) and the direct joining of step d) are performed in one in the same apparatus.

17. Production process according to one of the seven preceding claims, wherein the thickness of the film (2) deposited in step c) is less than or equal to 10 nm, or even less than or equal to 5 nm, or even less than or equal to 2 nm.

18. Production process according to one of the eight preceding claims, wherein steps c) and d) are performed in vacuum.

19. Production process according to one of the nine preceding claims, wherein deposition step c) is performed at ambient temperature, using a sputtering technique.

20. Production process according to one of the ten preceding claims, wherein the critical temperature is between 500° C. and 1800° C., depending on the nature of the metal material of the encapsulated film (2) and of the one or more semiconductor materials of the working layer (10) and of the carrier substrate (30).
